(19) United States
(12) Patent Application Publication
(10) Pub. No.: US 2012/0126423 A1
(43) Pub. Date: May 24, 2012

(54) SEMICONDUCTOR DEVICE MANUFACTURING METHOD AND SEMICONDUCTOR DEVICE

(75) Inventors: Yukinori Hatori, Nagano-shi (JP); Takashi Ozawa, Nagano-shi (JP)

(73) Assignee: SHINKO ELECTRIC INDUSTRIES CO., LTD., Nagano-shi (JP)

(21) Appl. No.: 13/301,154

(22) Filed: Nov. 21, 2011

(30) Foreign Application Priority Data
Nov. 23, 2010 (JP) 2010-260708

(51) Int. Cl. H01L 23/48; H01L 21/56

(52) U.S. Cl. 257/774; 438/127; 257/E23.011; 257/E21.502

(57) ABSTRACT

According to an aspect of the present invention, there is provided a semiconductor device manufacturing method, including: preparing a support plate having a mounting portion on which a mounting terminal is mountable; preparing a circuit board having a mounting surface on which a semiconductor chip is mounted and a connection pad is formed; bringing the support plate to face the mounting surface of the circuit board, and connecting the support plate to the connection pad through the mounting terminal; forming a resin layer between the support plate and the mounting surface of the circuit board to cover the mounting terminal; and removing the support plate, thereby faulting a via in the resin layer along a shape of the mounting portion so as to expose the mounting terminal therethrough.

### CROSS-REFERENCE TO RELATED APPLICATION(S)

This application claims priorities from Japanese Patent Application No. 2010-260708 filed on Nov. 23, 2010, the entire contents of which are incorporated herein by reference.

### FIELD

The present invention relates to a semiconductor device manufacturing method, and a semiconductor device.

### BACKGROUND

In electronic devices such as digital cameras and portable telephones, as realization of the functions, particularly in the image processing, advances, a so-called package-on-package (POP) form is often adapted in order to use two or more semiconductor packages. In the POP form, the semiconductor packages are stacked on each other.

There have been proposed various POP semiconductor packages.

For example, in U.S. Pat. No. 7,777,351-B, a semiconductor package is formed such that a molding resin layer as an insulating material is formed on a top surface of a lower circuit board, conical vias are formed in the insulating material, and solder balls are supplied in the vias so as to be connected with upper connection terminals on the lower circuit board. The top surfaces of the solder balls are exposed upwardly.

Alternatively, a semiconductor package may be formed such that solder balls are supplied to upper connection terminals on a lower circuit board, a molding resin layer as an insulating material is formed on the top surface of the lower circuit board to cover the solder balls, and conical vias are formed above the solder balls so as to upwardly expose the solder balls from the molding resin layer by performing a laser boring process on the molding resin layer.

In order to implement a POP structure, solder balls on the bottom surface of an upper circuit board are respectively arranged in the vias of the above-mentioned lower circuit board, and solder reflow processing is performed, thereby solder-connecting the upper circuit board and the lower circuit board with each other.

When the vias are formed in the lower circuit board by removing the molding resin layer with the laser boring process, it is extremely difficult to completely remove resin components from the surfaces of the solder balls.

If a resin component film remains on the surfaces of the solder balls, even when the solder reflow processing is performed, the solder balls of the lower circuit board will not be surely solder-connected with the solder balls of the upper circuit board. As a result, the reliability of the electrical connection between the boards in the semiconductor package will be deteriorated.

### SUMMARY

According to an aspect of the present invention, there is provided a semiconductor device manufacturing method, including: preparing a support plate having a mounting portion on which a mounting terminal is mountable; preparing a circuit board having a mounting surface on which a semiconductor chip is mounted and a connection pad is formed; bringing the support plate to face the mounting surface of the circuit board, and connecting the support plate to the connection pad through the mounting terminal; forming a resin layer between the support plate and the mounting surface of the circuit board to cover the mounting terminal; and removing the support plate, thereby forming a via in the resin layer along a shape of the mounting portion so as to expose the mounting terminal therethrough.

According to another aspect of the present invention, there is provided a semiconductor device, including: a circuit board having a mounting surface a semiconductor chip mounted on the mounting surface; a connection pad formed on the mounting surface; a mounting terminal formed on the connection pad; and a resin layer formed on the mounting surface to cover the mounting terminal, the resin layer having a via through which the mounting terminal is exposed, wherein the via is formed by removing a support plate which has abutted the mounting terminal at least when the mounting terminal was formed on the connection pad and the resin layer was formed on the mounting surface to cover the mounting terminal.

According to the above-mentioned aspects of the present invention, the mounting terminal of the semiconductor device is formed by being partly exposed through a via formed in the resin layer along the shape of the solder ball mounting portion on the support plate when the support plate is removed after the solder ball is connected to the connection pad, and the resin layer is formed between the mounting surface of the circuit board and the support plate. Thus, the surface of the solder ball serving as the mounting terminal is put into a clean state when the support plate is removed. Consequently, a residue of the molding resin can be surely prevented from remaining on the surface of the solder ball.

Accordingly, when a POP structure is formed by connecting the semiconductor package substrates to each other, the connection terminals thereof can surely be solder-connected to each other, thereby enhancing the reliability of the electrical connection therebetween.

### BRIEF DESCRIPTION OF DRAWINGS

FIG. 1 cross-sectional illustrates a semiconductor device according to a first embodiment.

FIG. 2A to 2I illustrate a method for manufacturing a semiconductor device according to the first embodiment.

FIGS. 3A to 3D illustrate a method for forming a solder ball mounting portion on a support plate.

FIGS. 4A to 4C illustrate a method for manufacturing a POP structure by stacking another circuit board on the manufactured semiconductor device.

FIG. 5 cross-sectional illustrates a semiconductor device according to a second embodiment.

FIGS. 6A to 6I illustrate a method for manufacturing a semiconductor device according to the second embodiment.

FIGS. 7A to 7H illustrate a method for forming a metal plating coat on a solder ball mounting portion on a support plate.

FIGS. 8A to 8D illustrate the concept of forming a solder ball mounted on a solder ball mounting portion via a metal plating film and transferring both of them onto a connection pad side of a circuit board.

FIGS. 9A to 9C illustrate a method for manufacturing a POP structure by stacking another circuit board on the manufactured semiconductor device.

FIGS. 10A to 10I illustrate another method for manufacturing a semiconductor device according to the second embodiment.

FIGS. 11A to 11D illustrate the concept of forming a metal plating film on a support plate and transferring it onto a solder ball side of a circuit board according to another manufacturing method.

### DETAILED DESCRIPTION

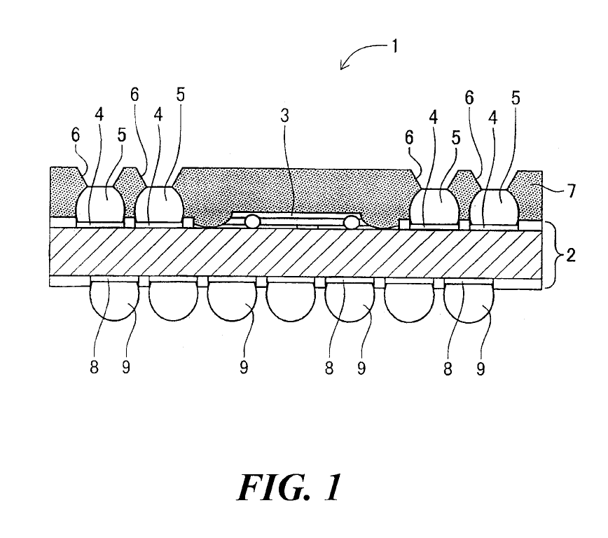

Hereinafter, a semiconductor device according to a first embodiment is described with reference to FIG. 1.

As illustrated in FIG. 1, a semiconductor device 1 according to the first embodiment has a circuit board 2. A semiconductor chip 3 is mounted on the top surface (i.e., a semiconductor chip mounting surface) of the circuit board 2. Two connection pads 4 are formed on both sides of the semiconductor chip 3. A solder ball 5 is mounted on each connection pad 4.

A molding resin layer 7 is formed on the top surface of the circuit board 2 so as to cover the semiconductor chip 3 and to upwardly expose the solder balls 5 through vias 6, respectively. The top surfaces of the solder balls 5 are put into a clean state when a copper support plate (to be described below) is removed by etching. Thus, there is no resin residue of the molding resin layer 7.

Plural connection terminals 8 are formed on the bottom surface of the circuit hoard 2. A solder ball 9 is mounted on each connection terminal 8.

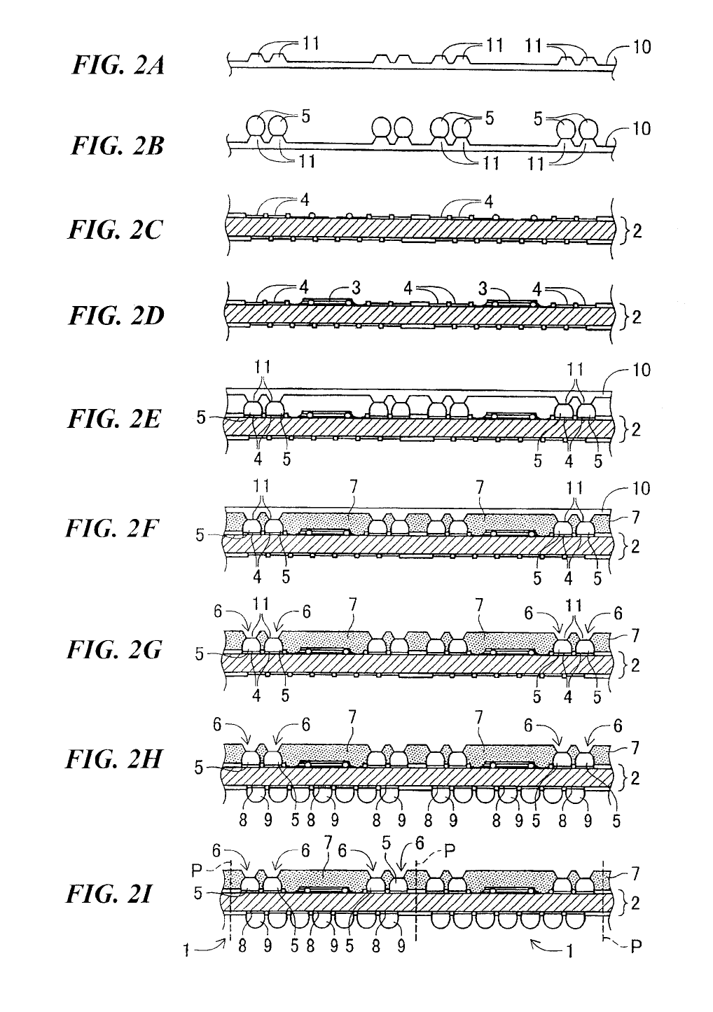

Next, a manufacturing method for the above-mentioned semiconductor device 1 is described hereinafter with reference to FIGS. 2A to 4C.

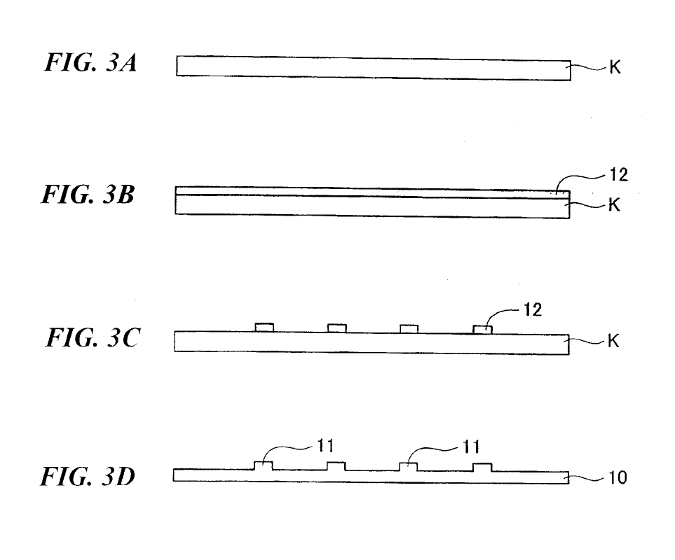

Referring to FIGS. 2A to 2I, first, a solder ball mounting portion 11, on which the solder ball 5 is to be mounted, is formed on a copper support plate 10 (see FIG. 2A). A method for forming the solder ball mounting portion 11 is described in detail with reference to FIGS. 3A to 3D.

First, a copper thin plate K is prepared as illustrated in FIG. 3A, and a photoresist film 12 is formed entirely on the top surface of the copper thin plate K as illustrated in FIG. 3B. Then, the photoresist film 12 is partially covered with a mask to open the part other than a part corresponding to each solder ball mounting portion 11, and the exposure and development are performed as normal. Consequently, as illustrated in FIG. 3C, only the part of the copper thin plate K, which corresponds to each solder ball mounting portion 11, is covered with the photoresist film 12.

Then, a so-called “half etching” is performed by immersing the copper thin plate K in copper etching solution. Consequently, the non-covered parts of the copper thin plate K are etched to be thin, while the covered parts of the copper thin plate K corresponding to the solder ball mounting portions 11 are maintained. Then, the resist film 12 is peeled. Thus, as illustrated in FIG. 3D, the copper support plate 10 having the solder ball mounting portions 11 is formed from the copper thin plate K.

Turning back to FIG. 2B, after the solder ball mounting portions 11 are formed on the copper support plate 10, a solder ball 5 is mounted on each solder ball mounting portion 11 by performing solder reflowing.

Then, flip chip mounting is performed on the circuit board 2 (see FIG. 2C), so that semiconductor chips 3 are mounted on the top surface of the circuit board 2 (see FIG. 2D).

The copper support plate 10 is faced to the circuit board 2 so that the solder balls 5 respectively abut the connection pads 4, and solder reflowing is performed to thereby respectively solder-connect the solder balls 5 to the connection pads 4, as illustrated in FIG. 2E.

Then, as illustrated in FIG. 2F, the space between the mounting surface of the circuit board 2 and the copper support plate 10 is filled with epoxy resin by a so-called transfer molding method. Thus, the molding resin layer 7 is formed.

Thereafter, etching is performed using, e.g., alkali etchant (manufactured by Meltex Incorporated (trade name is “A Process”) to selectively remove only the copper support plate 10 (see FIG. 2G)).

In this state, the vias 6 are formed in the molding resin layer 7 along the shapes of the solder ball mounting portions 11 formed on the copper support plate 10.

Further, the top surfaces of the solder balls 5 are brought into a clean state by the etchant when the copper support plate 10 is removed by etching, and there is no resin residue of the molding resin layer 7.

Solder reflowing may be additionally performed. Then, a solder ball 9 is mounted on each connection terminal 8 formed on the bottom surface of the circuit board 2, as illustrated in FIG. 2H.

Then, the circuit board 2 is cut at positions P illustrated in FIG. 2I via a blade into individual separated pieces, thereby manufacturing individual separated semiconductor devices 1. In each semiconductor device 1, the top portion of the solder hall 5, which is exposed from each via 6 formed in the molding resin layer 7, functions as a mounting terminal for connecting other circuit boards and the like.

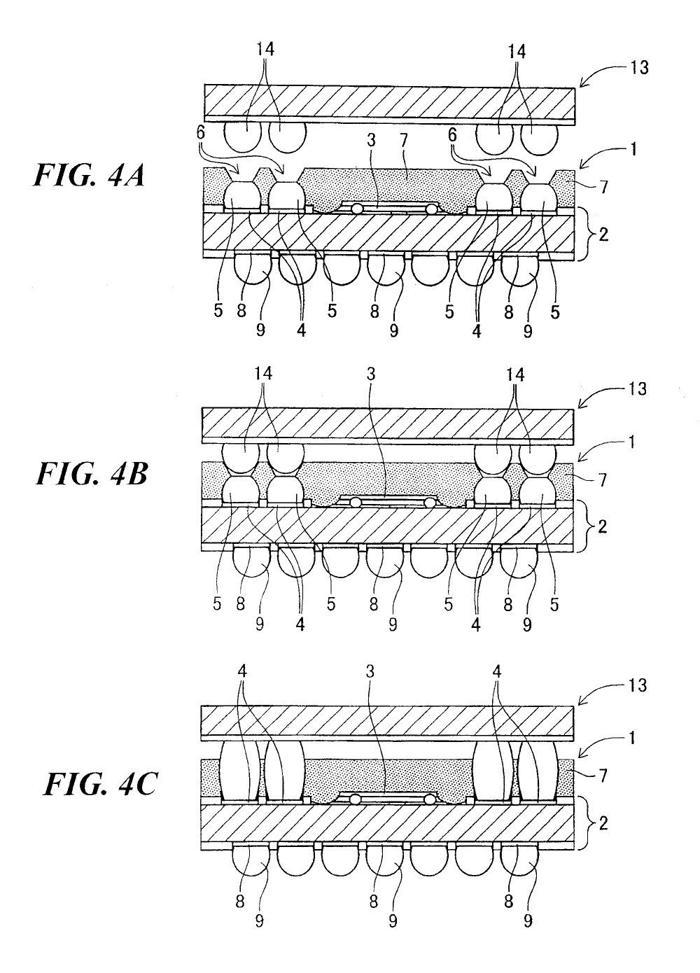

As illustrated in FIGS. 4A to 4C, another package substrate 13 is stacked on the above-mentioned semiconductor device 1, thereby forming a POP structure.

Hereinafter, a method for stacking another package substrate 13 on the semiconductor device 1 is described with reference to FIGS. 4A to 4C.

As illustrated in FIGS. 4A to 4C, a solder ball 14 is mounted on each connection terminal formed on the bottom surface of the package substrate 13. First, as illustrated in FIG. 4A, the solder balls 14 on the package substrate 13 are faced to the solder balls 5 on the semiconductor device 1, respectively. And, as illustrated in FIG. 4B, the solder balls 14 are arranged in the vias 6 from which the solder balls 5 are exposed, respectively. Thus, the package substrate 13 is pre-stacked on the semiconductor device 1.

Then, the solder reflowing is performed so that the solder balls 14 on the package substrate 13 and the solder balls 5 on the semiconductor device 1 are respectively melt-connected to each other, as illustrated in FIG. 4C.

On this occasion, the solder balls 14 on the package substrate 13 can easily be arranged in the respective vias 6 formed in the molding resin layer 7 of the semiconductor device 1 because the inverted-cone-like vias 6 expose the respective solder balls 5. Consequently, the package substrate 13 can be mounted easily and surely on the semiconductor device 1.

According to the first embodiment, when the copper support plate 10 is removed by etching, the top portion of each solder ball 5, which is exposed from an associated one of the vias 6 formed in the molding resin layer 7 of the semiconductor device 1, is maintained in a clean state in which no residue of the molding resin layer 7 remains. Consequently, the wettability of each solder ball 5 is enhanced. Thus, the solder balls 5 and the solder balls 14 are surely connected, respectively, and the electrical connection between the semiconductor device 1 and the package substrate 13 is enhanced.

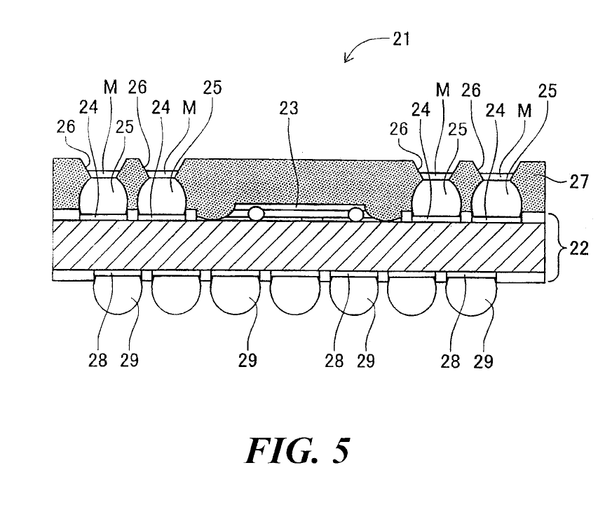

Next, a semiconductor device according to a second embodiment is described hereinafter with reference to FIGS. 5 to 9C.

As illustrated in FIG. 5, a semiconductor device 21 according to the second embodiment has a circuit board 22. A semiconductor chip 23 is mounted on the top surface (i.e., a semiconductor chip mounting surface) of the circuit board 22. Two connection pads 24 are formed on both sides of the semiconductor chip 23. A solder ball 25 is mounted on each connection pad 24.

A molding resin layer 27 is formed on the top surface of the circuit board 22 so as to cover the semiconductor chip 23 and to upwardly expose the solder balls 25 through vias 26, respectively. A metal plating film M formed by a method to be described below is formed on and covers the top surface of each solder ball 25 exposed from an associated one of the vias 26 formed in the molding resin layer 27.

Plural connection terminals 28 are formed on the bottom surface of the circuit board 22. A solder ball 29 is mounted on each connection terminal 28.

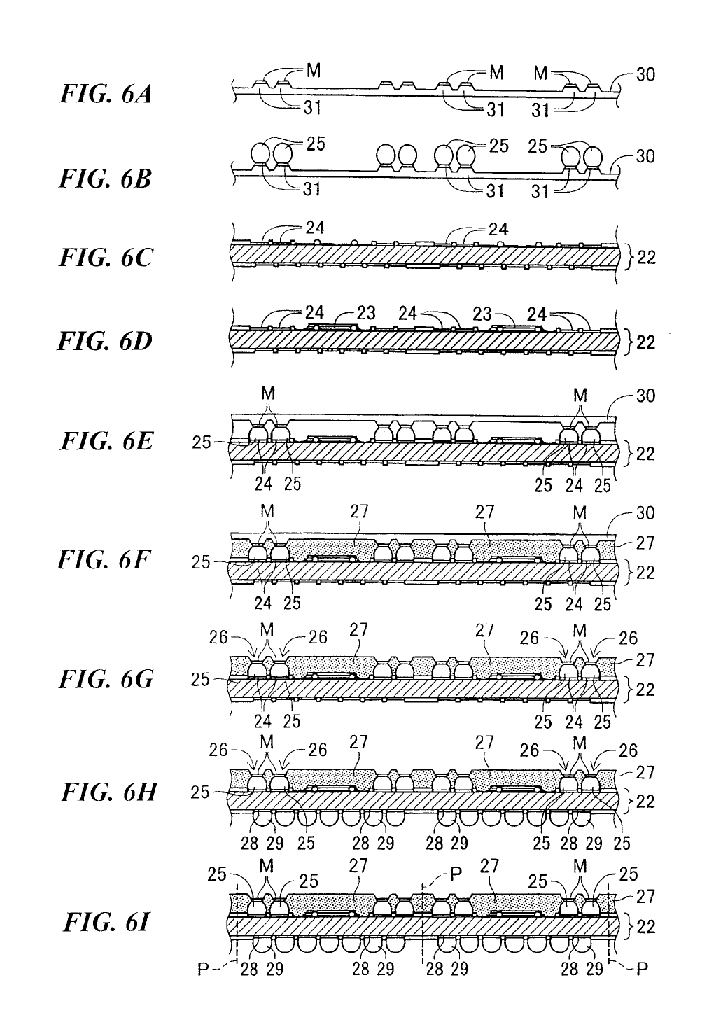

Next, a manufacturing method for the above-mentioned semiconductor device 2 is described hereinafter with reference to FIGS. 6A to 8D.

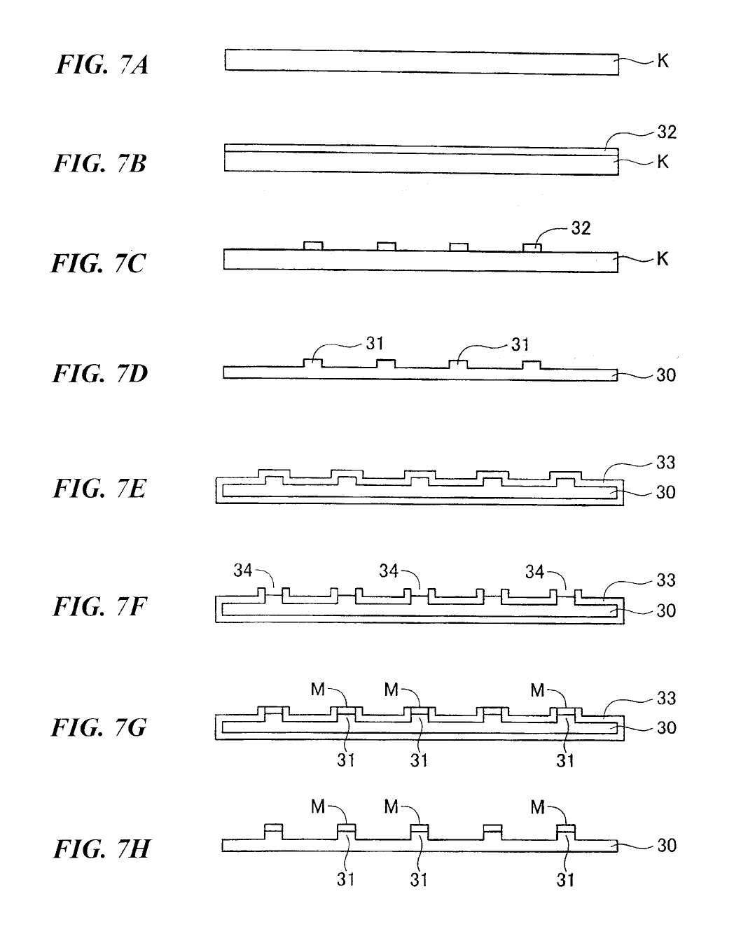

Referring to FIGS. 6A to 6I, first, a solder ball mounting portion 31, on which the solder ball 25 is to be mounted, is formed on a copper support plate 30 (see FIG. 6A). The metal plating films M are formed to cover the top surfaces of the solder ball mounting portions 31, respectively. A method for forming such a solder ball mounting portion 31, and a method for forming metal plating film M on the solder ball mounting portion 31 are described in detail with reference to FIGS. 7A to 7H.

First, a copper thin plate K is prepared as illustrated in FIG. 7A, and a photoresist film 32 is formed entirely on the top surface of the copper thin plate K as illustrated in FIG. 7B. Then, the photoresist film 32 is partially covered with a mask to open the part other than a part corresponding to each solder ball mounting portion 31, and the exposure and development are performed as normal. Consequently, as illustrated in FIG. 7C, only the part of the copper thin plate K, which corresponds to each solder ball mounting portion 31, is covered with the photoresist film 32.

Then, a so-called “half etching” is performed by immersing the copper thin plate K in copper etching solution. Consequently, the non-covered parts of the copper thin plate K are etched to be thin, while the covered parts of the copper thin plate K corresponding to the solder ball mounting portions 31 are maintained. Then, the resist film 32 is peeled. Thus, as illustrated in FIG. 7D, the copper support plate 30 having the solder ball mounting portions 31 is formed from the copper thin plate K.

Next, as illustrated in FIG. 7E, an electrodeposited resist film 33 prepared from acrylic polymer is formed on the entire surface of the copper support plate 30. Then, the top surface of the copper support plate 30, on which the solder ball mounting portions 31 are formed, is covered with a mask, and the exposure and development are performed as normal. Consequently, as illustrated in FIG. 7F, an opening 34 is fowled in the electrodeposited resist film 33 correspondingly with the solder ball mounting portions 31.

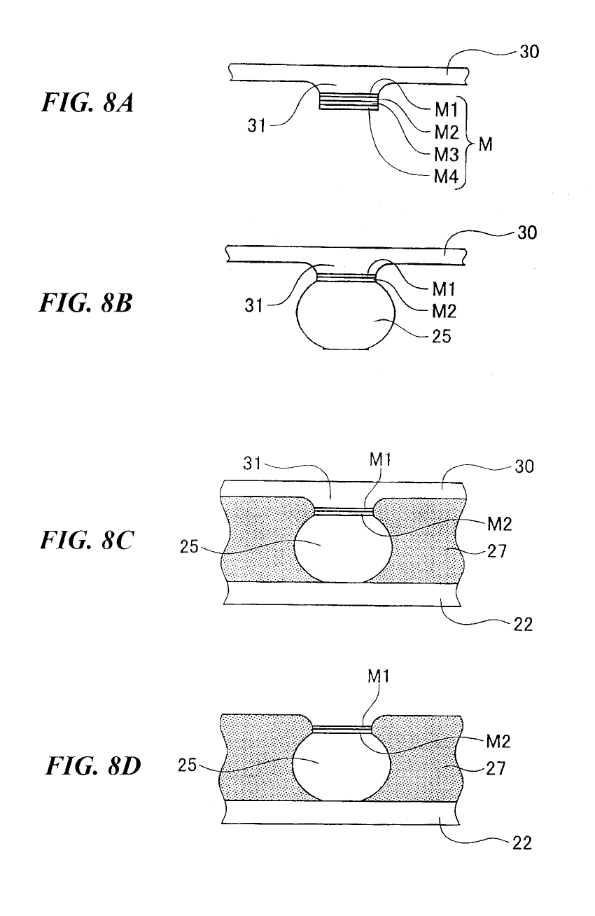

Then, as illustrated in FIG. 7G, the metal plating film M is formed on each solder hall mounting portion 31 through the opening 34. The metal plating film M have a four layer structure formed of a gold plating film M1, a palladium plating film M2. a nickel plating film M3. and a palladium plating film M4 arranged in this order outwardly from the side of the solder ball mounting portion 31 (see FIGS. 8A to 8D).

In order to form such a metal plating film M, first, the copper support plate 30, on which the electrodeposited resist film 33 having the opening 34 is formed, is immersed in a gold plating bath for a given time.

A plating solution retained in the gold plating bath is made up of 50 grams (g)/liter (l) of potassium citrate, and 50 g/l of tripotassium citrate.

Consequently, a first layer formed of a gold plating film M1 is formed on the solder ball mounting portion 31.

Next, the copper support plate 30 with the gold plating film M1 is immersed in a palladium plating bath for a given time. A plating solution retained in the palladium plating bath is made up of 150 g/l of potassium phosphate, and 15 of Pd(NH₃)₄Cl₂.

Consequently, a second layer formed of a palladium plating film M2 is formed on the gold plating film M1.

Next, the copper support plate 30 with the gold plating film M1 and the palladium plating film M2 is immersed in a nickel plating bath for a given time.

A plating solution retained in the nickel plating bath is made up of 320 g/l of nickel sulphamate.

Consequently, a third layer formed of a nickel plating film M3 is formed on the palladium plating film M2.

Finally, the copper support plate 30 with the first layer, i.e., the gold plating film M1, the second layer, i.e., the palladium plating film M2, and the third layer, i.e., the nickel plating film M3 is immersed in a palladium plating bath for a given time.

A plating solution retained in this palladium plating bath is made up of 150 g/l of potassium phosphate, and 15 g/l of Pd(NH₃)₄Cl₂.

Consequently, a fourth layer formed of a palladium plating film M4 is formed on the nickel plating film M3.

After the metal plating film M configured by the gold plating film M1, the palladium plating film M2, the nickel plating film M3 and the palladium plating film M4 is formed on the solder ball mounting portion 31, the electrodeposited resist film 33 is removed by etching. Thus, the copper support plate 30 in which the metal plating films M are respectively formed on the solder ball mounting portions 31 is obtained, as illustrated in FIG. 7H.

Turning back to FIG. 6B, after the solder ball mounting portions 31 each having the metal plating film M are formed on the copper support plate 30, a solder ball 25 is mounted on each solder ball mounting portion 31 by performing solder reflowing.

In the copper support plate 30, as shown in FIG. 8A, the metal plating film M initially has the four layer structure formed of the gold plating film M1, the palladium plating film M2, the nickel plating film M3, and the palladium plating film M4 arranged from the side of the solder ball mounting portion 31. And, the solder reflowing is performed by melting the solder balls 25 at a temperature equal to or higher than the melting point, as illustrated in FIG. 8B. Consequently, a solder alloy of the solder ball 25 and the nickel plating film M3 is formed. The outermost palladium plating film M4 is formed at the time of reflowing in order not only to prevent the oxidation of the nickel plating film M3, but also to contribute to the enhancement of wettability when being melt into the solder alloy. After the solder alloy is formed, the gold plating film M1 and the palladium plating film M2 maintain a two layer structure without change, and serves to prevent the oxidation of a nickel alloy.

Then, flip chip mounting is performed on the circuit board 22 (see FIG. 6C), so that semiconductor chips 23 are mounted on the top surface of the circuit board 22 (see FIG. 6D).

The copper support portion 30 is faced to the circuit board 22 so that the solder balls 25 respectively abut the connection pads 24, and solder reflowing is performed to thereby respectively solder-connect the solder balls 25 to the connection pads 24, as illustrated in FIG. 6E.

Then, as illustrated in FIG. 6F, the space between the mounting surface of the circuit board 22 and the copper support plate 30 is filled with epoxy resin by a so-called transfer molding method. Thus, the molding resin layer 27 is formed. FIG. 8C schematically illustrates this state. In FIG. 8C, illustration of the connection pad 24 is omitted.

Thereafter, etching is performed using, e.g., alkali etchant (manufactured by Meltex Incorporated (trade name is “A Process”) to selectively remove only the copper support plate 30 (see FIG. 6G)).

At that time, as illustrated in FIG. 8D, only the copper support plate 30 is removed by etching. The gold plating film M1 and the palladium plating film M2 that are formed on the solder ball mounting portion 31 maintain the two layer structure and remain at the side of the solder ball 25 so that the outer surfaces of the gold plating film M1 are respectively exposed from the vias 26 formed in the molding resin layer 27. When the copper support plate 30 is removed by etching, the surface of each gold plating film M1 is put into a clean state by etchant. Thus, there is no resin residue of the molding resin layer 27. Also in FIG. 8D, illustration of the connection pad 24 is omitted.

Solder reflowing may be additionally performed. Then, a solder ball 29 may be mounted on each connection terminal 28 formed on the bottom surface of the circuit board 22, as illustrated in FIG. 6H.

Then, the circuit board 22 is cut at positions P illustrated in FIG. 6I via a blade into individual separated pieces, thereby manufacturing individual separated semiconductor devices 21. In each semiconductor device 21, the gold plating film M1 exposed from each via 26 formed in the molding resin layer 27 functions as a mounting terminal for connecting other circuit boards and the like.

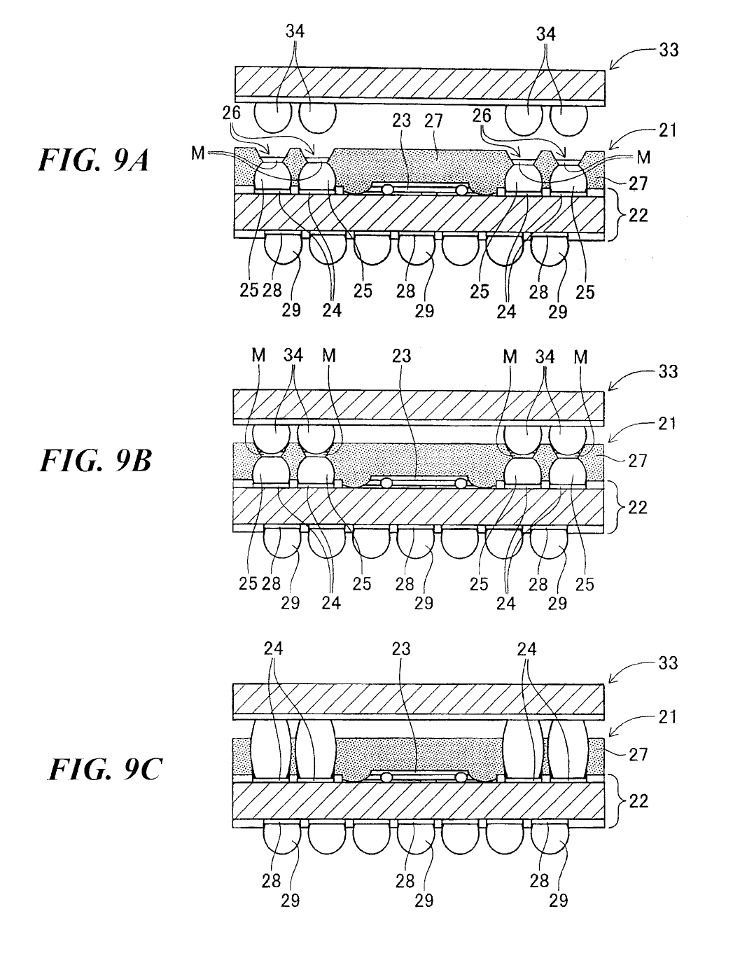

As illustrated in FIGS. 9A to 9C, another package substrate 33 is stacked on the above-mentioned semiconductor device 21, thereby forming a POP structure.

Hereinafter, a method for stacking another package substrate 33 on the semiconductor device 21 is described with reference to FIGS. 9A to 9C.

As illustrated in FIGS. 9A to 9C, a solder ball 34 is mounted on each connection terminal formed on the bottom surface of the package substrate 33. First, as illustrated in FIG. 9A, the solder balls 34 on the package substrate 33 are faced to the gold plating films M1 on the semiconductor device 21, respectively. And, as illustrated in FIG. 9B the solder balls 34 are arranged in the vias 26 from which the gold plating films M1 formed on the top surfaces of the solder balls 25 are exposed. Thus, the package substrate 33 is pre-stacked on the semiconductor device 21.

Then, the solder reflowing is performed so that the solder balls 34 on the package substrate 33 and the solder balls 25 on the semiconductor device 21 are respectively melt-connected to each other with the gold plating film M1 and the nickel plating film M2, as illustrated in FIG. 9C.

On this occasion, the solder balls 34 on the package substrate 33 can easily be arranged in the respective vias 26 formed in the molding resin layer 27 of the semiconductor device 21 because the inverted-cone-like vias 26 expose the respective solder balls 25. Consequently, the package substrate 33 can be mounted easily and surely on the semiconductor device 21.

According to the second embodiment, the metal plating film M having at least three layers of the gold plating film M1, the nickel plating film M2, and the palladium plating film M3 are formed on the solder ball mounting portions 31. In addition, after the copper support plate 30 is removed by etching, the metal plating films M remain at the side of the solder balls 25. The nickel plating film M2 and the gold plating film M1 formed on the top portion of each solder ball 25, which is exposed from an associated one of the vias 26 formed in the molding resin layer 27, is maintained in a clean state in which there is no residue of the molding resin layer 27, when the copper support plate 30 is subjected to etching. Consequently, the wettability of each solder ball 25 is enhanced. Thus, the solder balls 25 and the solder balls 34 are surely connected, respectively, and the electrical connection between the semiconductor device 21 and the package substrate 33 is enhanced.

The above-described embodiments are not limited to the above-described devices/methods as they are, and various improvements and modifications can be made without departing from the scope of the invention.

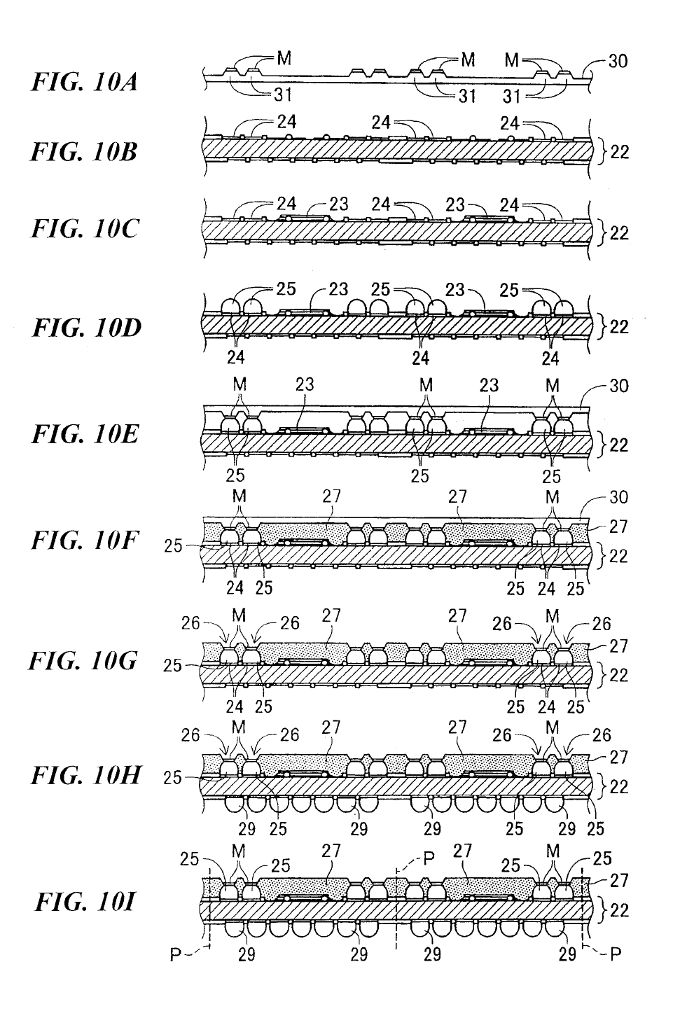

For example, in the second embodiment, the metal plating films M (each having the four layer structure formed of the gold plating film M1, the palladium plating film M2, the nickel plating film M3, and the palladium plating film M4) are respectively formed on the solder ball mounting portions 31 of the copper support plate 30. After the solder balls 25 are connected to the metal plating films M by solder reflowing (see FIGS. 6A and 6B), the solder balls 25 are connected to the connection pads 24 on the circuit board 22 (see FIG. 6E). However, the manufacturing method according to the invention is not limited thereto. The method illustrated in FIGS. 10A to 10I can be employed.

As illustrated in FIGS. 10A to 10I, the metal plating films M (each having the four layer structure formed of the gold plating film M1, the palladium plating film M2, the nickel plating film M3, and the palladium plating film M4) are respectively formed on the solder ball mounting portions 31 of the copper support plate 30 (see FIG. 10A). Then. each solder ball 25 is mounted on and connected to an associated connection pad 24 formed on the circuit board 22 through solder reflowing (see FIG. 10D). Thereafter, each solder ball mounting portion 31 formed on the copper support plate 30 is connected to an associated solder ball 25 by solder reflowing (see FIG. 10E).

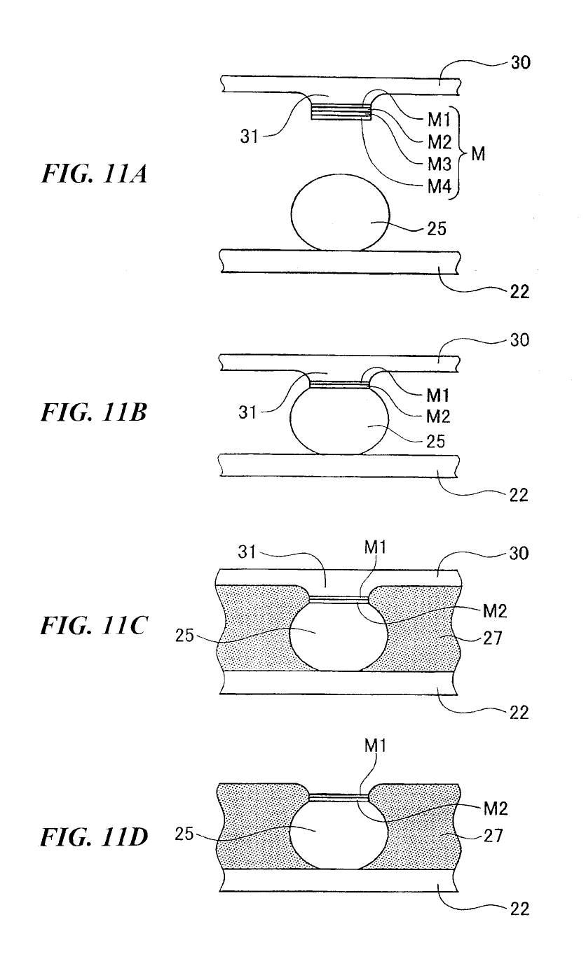

FIGS. 11A to 11D schematically illustrate the above method. In FIGS. 11A to 11D, illustration of the connection pad 24 is omitted. As illustrated in FIG. 11A, the metal plating film M formed on the copper support plate 30 initially has the four layer structure formed of the gold plating film M1, the palladium plating film M2, the nickel plating film M3, and the palladium plating film M4 arranged from the side of the solder ball mounting portion 31. After the metal plating film M formed on the solder bah mounting portion 31 of the copper support plate 30 is connected to the solder ball 25 formed on the circuit board 22, as illustrated in FIG. 11B, the solder ball 25 is melted at a temperature equal to or higher than the melting point and subjected to solder reflowing. Thus, a solder alloy of the solder ball 25, the outermost palladium plating film M4, and the next nickel plating film M3 is formed, while the palladium plating film M2 and the gold plating film M1 maintain their structure without change.

In addition, according to the so-called transfer molding method, the space between the mounting surface of the circuit board 22 and the copper support plate 30 is tilled with epoxy resin. Thus, the molding resin layer 27 is formed (see FIG. 11C). Thereafter, etching is performed with alkali etchant to selectively remove only the copper support plate 30 (FIG. 11D). Thus, only the copper support plate 30 is removed by etching. The gold plating film M1 and the palladium plating film M2 formed on the solder ball mounting portion 31 maintain a two layer structure and remain at the side of the solder ball 25. A surface of the gold plating film M1 existing on an outer side of the plating film M is exposed from each via 26 formed in the molding resin layer 27 and put into a clean state by etchant when the copper support plate 30 is removed by etching. Thus, there is no residue of the molding resin layer 7. And, the wettability of each solder ball 25 is enhanced. Thus, the solder balls 25 and the solder balls 34 are surely connected, respectively, and the electrical connection between the semiconductor device 21 and the package substrate 33 is enhanced.

The semiconductor device 21 and the manufacturing method therefor illustrated in FIGS. 10A to 11D are similar to those according to the second embodiment except the above-mentioned differences. Thus, the description of similar respects therebetween is omitted.

In the first and second embodiments, the solder balls 9, 29 are mounted on the connection terminals 8, 28 formed on the bottom surface of the circuit board 2, 22, respectively. However, if the semiconductor devices 1 and 21 are used in a land grid array (LGA) structure, it is unnecessary that the solder balls 9 and 29 are mounted on the connection terminals 8 and 28, respectively.

According to the first and second embodiments, the semiconductor chips 3, 23 are mounted on the circuit boards 2, 22 by flip chip mounting. The cases to which the first and second embodiments can be applied are not limited thereto. The first and second embodiments can be applied to the cases where the semiconductor chip is connected to the circuit hoard by wire bonding, and where the semiconductor device of the so-called chip stack type, in which two semiconductor chips are respectively stacked at upper and lower positions, is configured so that the upper semiconductor chip is mounted on the circuit board by wire bonding, and that the lower semiconductor chip is mounted thereon by flip chip mounting.

According to the first and second embodiments, the metal plating film M has the four layer structure formed of the gold plating film M1, the palladium plating film M2, the nickel plating film M3, and the palladium plating film M4. The structure of the metal plating film M is not limited thereto. The metal plating film M may have a three layer structure formed of e.g., a set of a gold plating film, a nickel plating film, and a palladium plating film, or a set of a gold plating film, a palladium plating film, and a gold plating film.

According to the first and second embodiments, the metal plating film is formed by plating. However, for example, the metal film may be formed by another method such as sputtering.

According to the first and second embodiments, the solder balls 5, 25 are formed as the mounting terminals on the copper support plate 10, 30 or on the circuit board 22 (connection pad 24) by solder reflowing. However, instead of the solder balls, mounting terminals may be formed, for example, by printing solder paste on the connection pad 24.

Instead of the solder balls 5, 25, Cu-core solder balls (solder coated Cu balls) may be used.

1. A semiconductor device manufacturing method, comprising:
preparing a support plate having a mounting portion on which a mounting terminal is mountable:
preparing a circuit board having a mounting surface on which a semiconductor chip is mounted and a connection pad is formed;
bringing the support plate to face the mounting surface of the circuit board, and connecting the support plate to the connection pad through the mounting terminal;
forming a resin layer between the support plate and the mounting surface of the circuit hoard to cover the mounting terminal; and
removing the support plate, thereby forming a via in the resin layer along a shape of the mounting portion so as to expose the mounting terminal therethrough.

2. The method of claim 1,
wherein a metal film is formed on the mounting portion of the support plate, and
wherein the metal film is interposed between the support plate and the mounting terminal when the mounting terminal is mounted on the mounting portion, and remains on the mounting terminal when the support plate is removed.

3. The method of claim 2,
wherein the metal film includes a plurality of metal films, one metal film thereof contacting the mounting terminal and forming an alloy therewith upon being heated at a temperature equal to or higher than a melting point of the mounting terminal.

4. The method of claim 3.
wherein, when the support plate is removed, while the one metal film has been formed into the alloy with the mounting terminal, the other metal films remain on a surface of the alloy.

5. The method of claim 1,
wherein the support plate is removed by etching.

6. A semiconductor device, comprising:
a circuit board having a mounting surface
a semiconductor chip mounted on the mounting surface;
a connection pad formed on the mounting surface;
a mounting terminal formed on the connection pad; and
a resin layer formed on the mounting surface to cover the mounting terminal, the resin layer having a via through which the mounting terminal is exposed,
wherein the via is formed by removing a support plate which has abutted the mounting terminal at least when the mounting terminal was formed on the connection pad and the resin layer was formed on the mounting surface to cover the mounting terminal.

7. The device of claim 6,
wherein a metal film was formed on a mounting portion of the support plate, and
wherein the metal film was interposed between the support plate and the mounting terminal when the mounting terminal was mounted on the mounting portion, and remained on the mounting terminal when the support plate was removed.

8. The device of claim 7.
wherein the metal film has included a plurality of metal films, one metal film thereof contacting the mounting terminal and forming an alloy therewith upon being heated at a temperature equal to or higher than a melting point of the mounting terminal.

9. The device of claim 8,
wherein, when the support plate is removed, while the one metal film has been formed into the alloy with the mounting terminal, the other metal films remain on a surface of the alloy.

10. The method of claim 1,
wherein the support plate is completely removed.

11. The method of claim 1,
wherein the mounting terminal comprises solder.
